(19) United States
(12) Patent Application Publication
(10) Pub. No.: US 2025/0236158 A1
(43) Pub. Date: Jul. 24, 2025

(54) ACCOMMODATION DEVICE AND AUTOMATED TRANSPORT CARRIER AND OPERATION METHOD THEREOF

(71) Applicant: Innolux Corporation, Miaoli County (TW)

(72) Inventors: Chien-Wei Chen, Miaoli County (TW); Chi-Feng Li, Miaoli County (TW); Hsin-Yi Hsu, Miaoli County (TW); Chong-Lin Huang, Miaoli County (TW); Wei-Cheng Lai, Miaoli County (TW)

(73) Assignee: Innolux Corporation, Miaoli County (TW)

(21) Appl. No.: 19/002,755

(22) Filed: Dec. 27, 2024

(30) Foreign Application Priority Data
Jan. 18, 2024 (TW) 113101954

(51) Int. Cl. B60H 3/06; F24F 7/003; H01L 21/677

(52) U.S. Cl. CPC B60H 3/06; F24F 7/003; H01L 21/67724

(57) ABSTRACT

An accommodation device includes a plurality of walls, a partition, and an air blowing unit. The walls define an accommodation space. The partition is disposed in the accommodation space to divide the accommodation space into a first area and a second area. The air blowing unit is disposed in the first area and blows an air to the first area.

### CROSS-REFERENCE TO RELATED APPLICATION

This application claims the priority benefit of Taiwan application serial no. 113101954, filed on Jan. 18, 2024. The entirety of the above-mentioned patent application is hereby incorporated by reference herein and made a part of specification.

### BACKGROUND

### Technical Field

The disclosure relates to an accommodation device, an automated transport carrier, and an operation method thereof, and in particular relates to an accommodation device that may prevent an object from being damaged during transport, an automated transport carrier having the accommodation device, and an operation method thereof.

### Description of Related Art

After a semiconductor element is applied to a panel-type carrier board (such as a steel board) in a semiconductor manufacturing factory, the panel-type carrier board still needs to be transported by personnel. However, in the process of personnel transport, in addition to the risk of the carrier board hitting the machine equipment, object, or personnel, it is also easy to cause damage to the semiconductor element on the carrier board, and since large-scale transfer is needed, the degree of contamination of the semiconductor element on the carrier board by suspended particles may not be reduced.

### SUMMARY

The disclosure provides an accommodation device, an automated transport carrier, and an operation method thereof that may reduce the probability of damaging an object during transport and reduce the degree of suspended particles contaminating an object such as a semiconductor element during transport.

An accommodation device of the disclosure includes a plurality of walls, a partition, and an air blowing unit. The walls define an accommodation space. The partition is disposed in the accommodation space to divide the accommodation space into a first area and a second area. The air blowing unit is disposed in the first area and blows an air to the first area.

An automated transport carrier of the disclosure includes a mobile base and an accommodation device. The accommodation device is disposed on the mobile base. The accommodation device includes a plurality of walls, a partition, and an air blowing unit. The walls define an accommodation space. The partition is disposed in the accommodation space to divide the accommodation space into a first area and a second area. The air blowing unit is disposed in the first area and blows an air to the first area.

An operation method of an automated transport carrier of the disclosure includes the following steps. An automated transport carrier is provided. The automated transport carrier includes an accommodation device, and the accommodation device includes an air blowing unit. The accommodation device is made to receive an object. The air blowing unit is made to blow an air to an inside of the accommodation device.

Based on the above, in the design of the accommodation device of the disclosure, the walls may define the accommodation space, and the partition may divide the accommodation space into the first area and the second area. The air blowing unit disposed in the first area may blow the air to the first area. Compared with the prior art of using personnel to transport the object, when the accommodation device of the automated transport carrier of the disclosure receives the object, in addition to replacing the existing manual transport, since the accommodation device includes the design of the walls, and the object may be effectively protected to reduce the risk of damage to the object during transport. In addition, since the accommodation device of the disclosure includes the air blowing unit, the degree of contamination of the object by suspended particles may be effectively reduced.

In order to make the aforementioned features and advantages of the disclosure more comprehensible, embodiments accompanied with figures are described in detail below.

### BRIEF DESCRIPTION OF THE DRAWINGS

FIG. 1A is a schematic three-dimensional view of an automated transport carrier according to an embodiment of the disclosure.

FIG. 1B is a partial schematic three-dimensional view of the automated transport carrier of FIG. 1A from another perspective.

FIG. 2 is a partial schematic view of the accommodation device of the automated transport carrier of FIG. 1A.

FIG. 3A is a schematic three-dimensional view of the conveying module and the lifting module in the automated transport carrier of FIG. 1A.

FIG. 3B is a schematic top view of the transport module of the automated transport carrier of FIG. 1A.

FIG. 3C is a three-dimensional view of the second guide group in FIG. 3B.

FIG. 3D is an enlarged top view of the first guide group in FIG. 3B.

FIG. 4 is a schematic flowchart of an operation method of an automated transport carrier according to an embodiment of the disclosure.

FIG. 5A is a schematic flowchart of an operation method of another automated transport carrier according to an embodiment of the disclosure.

FIG. 5B is a schematic flowchart of an operation method of another automated transport carrier according to an embodiment of the disclosure.

### DESCRIPTION OF THE EMBODIMENTS

The disclosure may be understood by referring to the following detailed description in combination with the accompanying drawings. It should be noted that in order to make it easy for readers to understand and for the simplicity of the drawings, many of the drawings in the disclosure depict portions of an electronic device, and certain elements in the drawings are not drawn to actual scale. In addition, the number and size of elements in the figures are for illustration and are not intended to limit the scope of the disclosure.

Throughout the disclosure, certain words are used to refer to specific elements in the specification and the claims. Those skilled in the art should understand that electronic equipment manufacturers may refer to the same elements by different names. The specification does not intend to distinguish between elements having the same function but different names.

In the following description and claims, the words “contain”, “have”, and “include” and the like are open-ended words, and therefore should be interpreted as “including but not limited to . . . ”

In addition, relative terms, such as “below” or “bottom” and “above” or “top”, may be used in the embodiments to describe the relative relationship of one element of the figure to another element. It may be understood that if the device in the figures is turned upside down, elements described as being on the “lower” side are then elements described as being on the “upper” side.

In some embodiments of the disclosure, terms related to joining and connecting such as “connection”, “interconnection”, etc., unless otherwise defined, may mean that the two structures are in direct contact, or may also mean that the two structures are not in direct (indirect) contact, wherein there are other structures provided between the two structures. Moreover, the terms about joining and connecting may also include the situation where both structures are movable, or both structures are fixed. Moreover, the term “coupling” includes the transfer of energy between two structures via direct or indirect electrical connection means, or the transfer of energy between two separate structures via mutual induction means.

It should be understood that when an element or layer is referred to as being “on” or “connected to” another element or layer, it may be directly on or directly connected to the other element or layer, or there may be an intervening element or layer between the two (indirect cases). In contrast, when an element is referred to as being “directly on” or “directly connected to” another element or layer, there are no intervening elements or layers present.

The terms “about”, “equal to”, “equal” or “same”, “substantially” or “essentially” are generally interpreted as within 20% of the given value or range, or interpreted as within 10%, 5%, 3%, 2%, 1%, or 0.5% of a given value or range.

As used herein, the terms “film” and/or “layer” may refer to any continuous or discontinuous structure and material (such as a material deposited by a method disclosed herein). For example, the film and/or the layer may include a two-dimensional material, a three-dimensional material, a nanoparticle, or even a partial or complete molecular layer, or a partial or complete atomic layer, or a cluster of atoms and/or molecules. The film or the layer may include a material or a layer having a pinhole, and may be at least partially continuous.

Although the terms first, second, third . . . may be used to describe various constituent elements, the constituent elements are not limited to these terms. These terms are used to distinguish a single element from other constituent elements in the specification. The same terms may be not used in the claims, but are replaced by first, second, third . . . in the order in which elements are declared in the claims. Therefore, in the following description, a first constituent element may be a second constituent element in the claims.

Unless otherwise defined, all terms (including technical and scientific terms) used herein have the same meaning as commonly understood by one of ordinary skill in the art to which this disclosure belongs. It may be understood that these terms, such as those defined in commonly used dictionaries, should be interpreted as having a meaning consistent with the background or context of the related techniques and the disclosure, and should not be interpreted in an idealized or overly formal manner, unless otherwise defined herein.

It should be noted that, in the following embodiments, without departing from the spirit of the disclosure, technical features in several different embodiments may be replaced, reorganized, and mixed to complete other embodiments.

An electronic device of the disclosure may include a transport carrier that may be used to transport a display device, an antenna device, a sensing device, a light-emitting device, a tiling device, or an electronic element, but the disclosure is not limited thereto. The electronic device may include a bendable or flexible electronic device. The electronic device may include an electronic element. The electronic element may include a passive element, an active element, or a combination of the above, such as a capacitor, a resistor, an inductor, a variable capacitor, a filter, a diode, a transistor, a sensor, a microelectromechanical system element (MEMS), a liquid-crystal chip, a wafer, an integrated circuit, or a die, etc., but the disclosure is not limited thereto. The diode may include a light-emitting diode or a non-light-emitting diode. The diode includes a P-N junction diode, a PIN diode, or a constant current diode. The light-emitting diode may include, for example, an organic light-emitting diode (OLED), a mini LED, a micro LED, a quantum dot LED, fluorescence, phosphor, or other suitable materials, or a combination of the above, but the disclosure is not limited thereto. The sensor may include, for example, a capacitive sensor, an optical sensor, an electromagnetic sensor, a fingerprint sensor (FPS), a touch sensor, an antenna, or a pen sensor, but the disclosure is not limited thereto. In the following, the transport carrier is used as the electronic device to illustrate the content of the disclosure, but the disclosure is not limited thereto.

It should be understood that, according to an embodiment of the disclosure, the depth, thickness, width, or height of individual elements, or the spacing or distance between elements may be measured using an optical microscope (OM), a scanning electron microscope (SEM), a film thickness profile measuring instrument (a-step), an ellipse thickness gauge, or other suitable methods. According to some embodiments, a scanning electron microscope may be used to obtain a cross-sectional structural image containing the element to be measured, and measure the depth, thickness, width, or height of each element, or the spacing or distance between elements.

Hereinafter, exemplary embodiments of the disclosure are described in detail, and examples of the exemplary embodiments are conveyed via the figures. Wherever possible, the same reference numerals are used in the figures and the descriptions to refer to the same or similar portions.

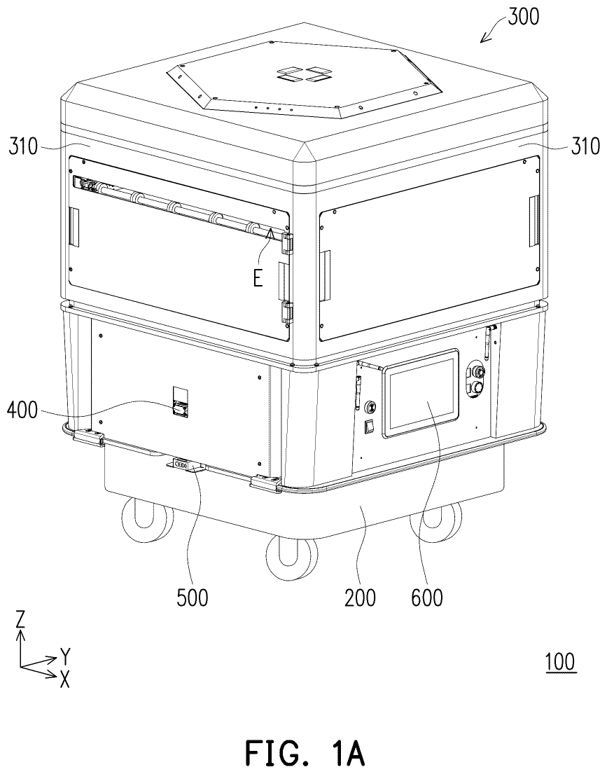

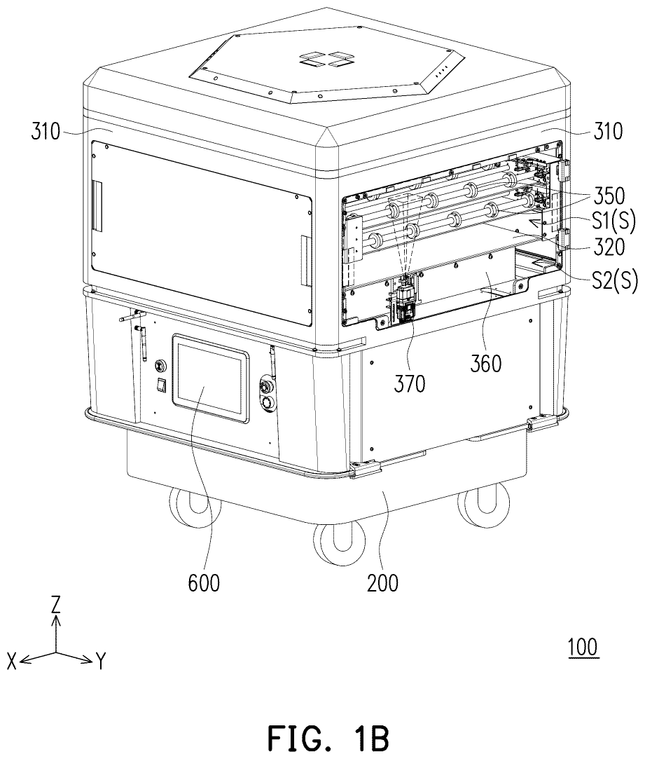

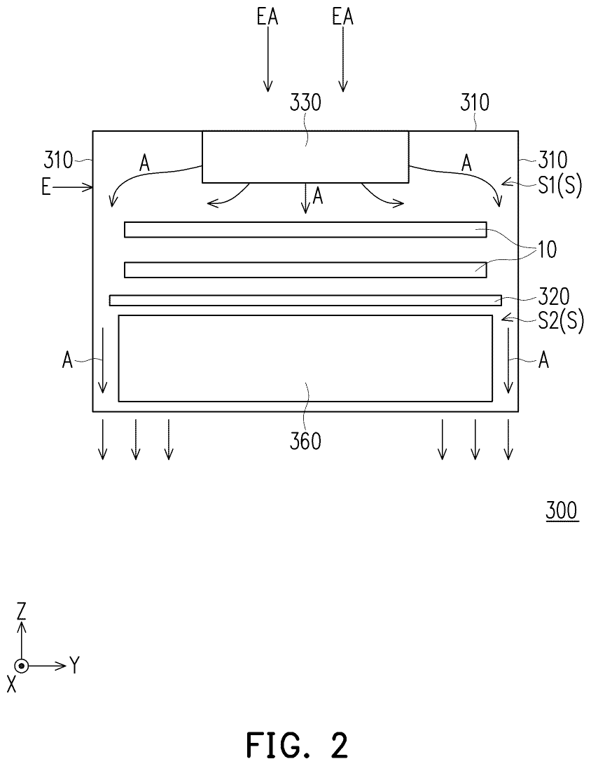

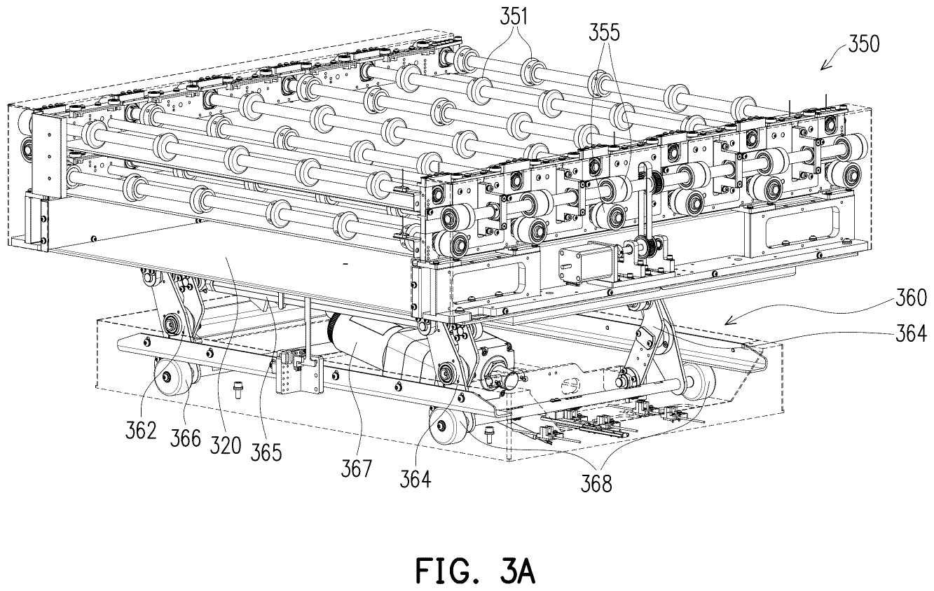

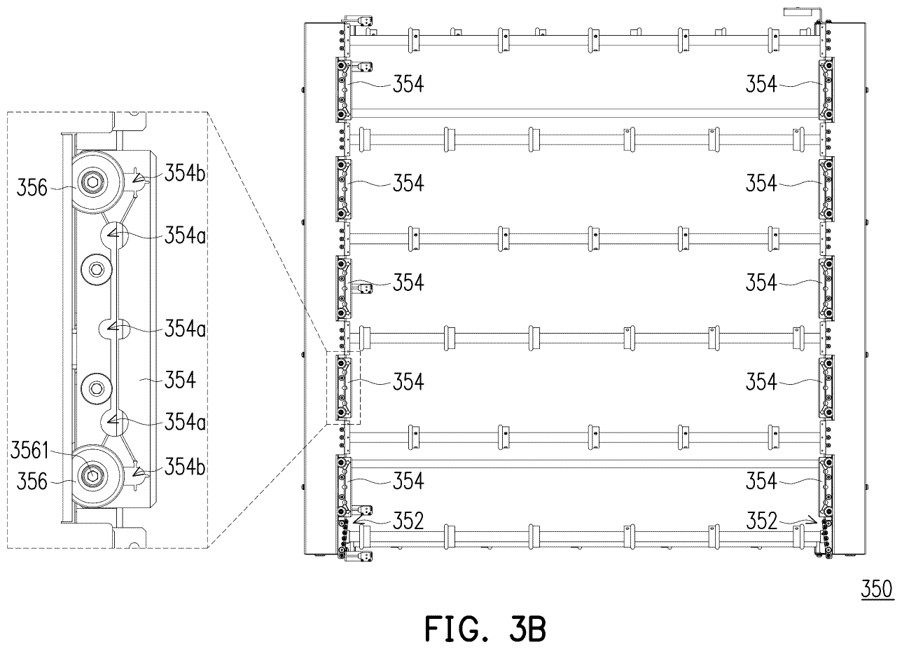

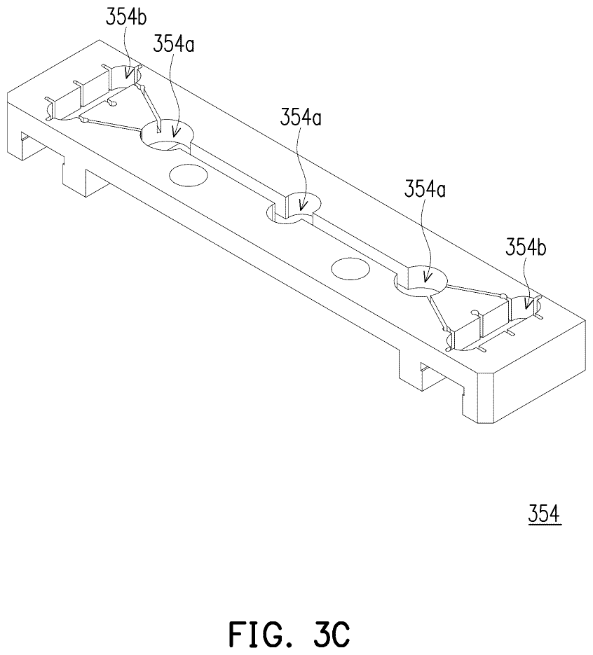

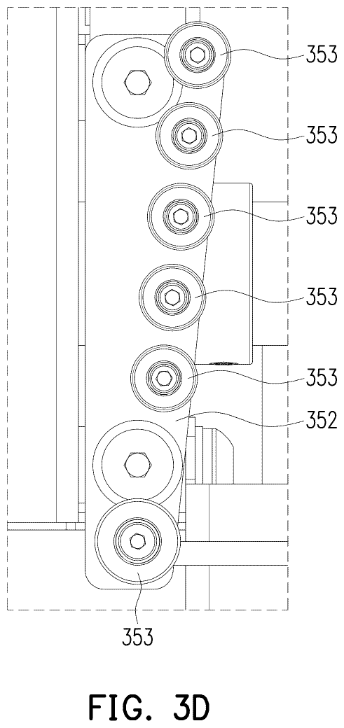

FIG. 1A is a schematic three-dimensional view of an automated transport carrier according to an embodiment of the disclosure. FIG. 1B is a partial schematic three-dimensional view of the automated transport carrier of FIG. 1A from another perspective. FIG. 2 is a partial schematic view of the accommodation device of the automated transport carrier of FIG. 1A. FIG. 3A is a schematic three-dimensional view of the conveying module and the lifting module in the automated transport carrier of FIG. 1A. FIG. 3B is a schematic top view of the transport module of the automated transport carrier of FIG. 1A. FIG. 3C is a three-dimensional view of the second guide group in FIG. 3B. FIG. 3D is an enlarged top view of the first guide group in FIG. 3B.

Please refer to FIG. 1A and FIG. 1B at the same time. In the present embodiment, an automated transport vehicle 100 includes a mobile base 200 and an accommodation device 300, wherein the accommodation device 300 is disposed on the mobile base 200. In an embodiment, the mobile base 200 is, for example, a mechanism having a rolling member, such as a mechanism having a wheel that may carry the accommodation device 300 and having a moving function. In an embodiment, the automated transport carrier 100 has an inlet/outlet E to transport an object 10 (please refer to FIG. 2) to or from the accommodation device 300. Therefore, the object 10 may be moved in a wide range between semiconductor production lines via the automated transport carrier 100 to replace manual transport in the prior art. In an embodiment, the dimensions of the automated transport carrier 100 are, for example, a length (along the X-axis direction) of 886 millimeters (mm), a width (along the Y-axis direction) of 886 mm, and a height (along the Z-axis direction) of 1206.8 mm, but the disclosure is not limited thereto. In an embodiment, the overall weight of the automated transport carrier 100 is, for example, 202.2 kilograms, but the disclosure is not limited thereto.

Please refer to FIG. 1B and FIG. 2. In the present embodiment, the accommodation device 300 includes a plurality of walls 310, a partition 320, and an air blowing unit 330. The walls 310 may define an accommodation space S to accommodate the object 10. The partition 320 is disposed in the accommodation space S to divide the accommodation space S into a first area S1 and a second area S2. The air blowing unit 330 is disposed in the first area S1 and blows an air A to the first area S1. Here, the first area S1 is adjacent to the air blowing unit 330, and the first area S1 may be used to accommodate the object 10.

Specifically, in the present embodiment, the first area S1 and the second area S2 of the accommodation space S are disposed up and down, for example, along the height direction of the accommodation device 300 (i.e., the Z-axis). In an embodiment, the object 10 may include a carrier board and at least one electronic element disposed on the carrier board, the carrier board is, for example, a panel-type steel board, and the length and width thereof are, for example, 700 mm in length (along the X-axis direction) and 700 mm in width (along the Y-axis direction). The carrier board may be disposed in the first area S1 through the inlet/outlet E (please refer to FIG. 1A), but the disclosure is not limited thereto. In an embodiment, the electronic element on the carrier is, for example, a chip or a die produced by a semiconductor process, but the disclosure is not limited thereto. The air blowing unit 330 is adapted to suck in an external air EA and blow the air A to the inside of the accommodation device 300 (i.e., the first area S1). In an embodiment, the cleanliness of the air A is higher than the cleanliness of the external air EA. In other words, the cleanliness of the air A in the accommodation space S is better than the cleanliness of the external air EA. The air blowing unit 330 may be, for example, a fan filter unit (FFU) to effectively filter out 99.99% of suspended particles having a minimum size greater than or equal to 0.3 micrometers (um) in the external air EA to improve the cleanliness of the blown air A, but the disclosure is not limited thereto. The partition 320 is separated from at least one of the walls 310 so that the air A may flow from the first area S1 to the second area S2. The air flow design may increase the probability of blowing away the suspended particulate contamination sources on the surface of the object 10 located in the first area S1 via the flow of the air A and moving the suspended particulate contamination sources to the second area S2.

More specifically, the pressure in the accommodation space S of the accommodation device 300 may be greater than the external pressure outside the accommodation device 300 to ensure that the suspended particles in the accommodation space S may be discharged from the bottom of the accommodation device 300 and reduce the intrusion of external suspended particles into the accommodation space S contaminating the device 10. In an embodiment, the pressure in the accommodation space S is, for example, 0.144 Pa, and the external pressure is, for example, 0 Pa, but the disclosure is not limited thereto. In an embodiment, the blowing air volume of the air blowing unit 330 needs to at least be able to discharge suspended matter and prevent external suspended matter from entering the accommodation space S. In an embodiment, the blowing air volume of the air blowing unit 330 is, for example, between 1.5 cubic meters per minute (m³/min) and 5 m³/min, but the disclosure is not limited thereto. In an embodiment, the blowing air volume of the air blowing unit 330 is preferably, for example, 2 m³/min to 3.5 m³/min. In an embodiment, the accommodation space S of the accommodation device 300 may reach, for example, Class 10 dustproof level to reduce the contamination of suspended particles during transport of the object 10.

Referring further to FIG. 2, in an embodiment, when the first area S1 of the accommodation space S carries, for example, two objects 10, the air blowing unit 330 at the top blows out the air A to first clean the surface of the uppermost object 10. At this point, the suspended particles may be discharged through the inlet/outlet E at the side, or they may be accumulated to the bottom of the accommodation device 300 through the air flow path and discharged through the bottom opening. That is, there are two discharge openings, one is the inlet/outlet E at the side, and the other is the bottom opening of the accommodation device 300. In an embodiment, when the uppermost object 10 is transported out through the inlet/outlet E, the object 10 below is lifted up by the lifting module 360 below the partition 320. Then, the air blowing unit 330 at the top blows out the air A to clean the surface of the lifted object 10. At this point, the suspended particles may be discharged through the inlet/outlet E at the side, or they may be accumulated to the bottom of the accommodation device 300 through the air flow path and discharged through the bottom opening. In an embodiment, when the object 10 below is also transported out through the inlet/outlet E (that is, the two objects 10 located at the first area S1 are both sent out), at this time, the air blowing unit 330 at the top may continue to blow out the air A to clean the accommodation space S to blow the suspended particles in the accommodation space S to the bottom of the accommodation device 300 through the air flow path to discharge the suspended particles through the bottom opening to ensure the cleanliness in the accommodation space S. In other words, the first area S1 of the accommodation space S may or may not carry the object 10, and the object 10 may be placed at any position (such as above or below) of the first area S1.

An operation method of the automated transport carrier 100 may include the following steps. Please refer to FIG. 1A and FIG. 2 at the same time. First, the automated transport carrier 100 is provided, wherein the automated transport carrier 100 includes the accommodation device 300, and the accommodation device 300 includes the air blowing unit 330. Next, the accommodation device 300 is made to receive the object 10. Lastly, the air blowing unit 330 is made to blow the air A to an inside of the accommodation device 300.

In short, when the accommodation device 300 of the automated transport carrier 100 of the present embodiment receives the object 10, in addition to transporting the object 10 via the automated transport carrier 100 to replace the existing manual transport, also, since the accommodation device 300 includes the design of the walls 310, the object 10 may be protected and the risk of damage to the object 10 during transport is avoided. In addition, since the accommodation device 300 of the present embodiment includes the air blowing unit 330, the degree of contamination of the object 10 by suspended particles may be reduced.

Please refer further to FIG. 1A and FIG. 1B. In an embodiment, the automated transport carrier 100 may include a traveling direction protection detection design to reduce the probability of the automated transport carrier 100 colliding with an obstacle while walking. The automated transport carrier 100 may also include a lateral shift detection alignment sensor 400 to provide accurate positioning to ensure the accuracy and/or reliability of loading/unloading a material. In an embodiment, the lateral shift detection alignment sensor 400 is, for example, a charge-coupled device (CCD) photo sensor, but the disclosure is not limited thereto. In an embodiment, the lateral shift detection alignment sensor 400 may also include an optical character recognition (OCR) function to identify and locate the identification number of the machine where the object 10 is to be entered/exited, and compare the identification number with the control system, thereby reducing an accident such as docking to the wrong machine. In an embodiment, the automated transport carrier 100 may also include a programmed input/output (PIO) communication module 500 to comply with the Semiconductor Production Line Equipment Information Security Standard (SEMI) and support the E84 (Handoff Parallel I/O Interface) standard, but the disclosure is not limited thereto. Moreover, in an embodiment, the automated transport carrier 100 may also include a display device 600 to display information of the object 10 loaded in the accommodation device 300, and may also display a received control instruction. When the display device 600 includes a touch function, the user may also input the control instruction, but the disclosure is not limited thereto.

Furthermore, please refer to both FIG. 1B and FIG. 3A. In the present embodiment, the accommodation device 300 may also be provided with a conveying platform, wherein the conveying platform includes a conveying module 350 and a lifting module 360 located below the conveying module 350. The transport module 350 may be used to transport the object 10 (please refer to FIG. 2), so that the object 10 may enter and leave the accommodation device 300 through the inlet/outlet E of the automated transport carrier 100. In an embodiment, the conveying module 350 adopts a conveying mode of a roller 351, for example, wherein the conveying module 350 adopts magnetic rings 355 disposed staggered up and down. Power is transmitted in a non-contact manner via the mutual repulsion of magnetic forces between the upper and lower magnetic rings 355 (for example, the upper magnetic ring 355 is rotated clockwise and the lower magnetic ring 355 is rotated counterclockwise) to solve the contamination source caused by the particles produced by wear and tear when operated for a long time via the contact mode (such as a gear set) in the existing techniques, and may be equipped with a stainless steel cover, for example, to appropriately separate the conveying module 350. In other words, the magnetic rings 355 of the present embodiment utilize the attraction/repulsion principle of magnetic force to perform transmission in a non-contact manner without gear engagement. In an embodiment, in order to achieve the Class 10 dust-free level, the roller 351 made of a material having antistatic (for example, resistance value 10⁶ to 10¹⁰) and low dust generation (for example, antistatic polymer polyethylene (UPE)) may be used to transport the object 10.

Furthermore, referring to FIG. 3B, FIG. 3C, and FIG. 3D at the same time, in the present embodiment, the conveying module 350 may also include a plurality of first guide groups 352 (two first guide groups 352 are schematically shown), a plurality of second guide groups 354 (ten second guide groups 354 are schematically shown), and a plurality of bearings 353 and 356. The first guide groups 352 are opposite (i.e., disposed left and right) and disposed symmetrically and adjacent to the inlet/outlet E of the automated transport carrier 100, and the second guide groups 354 are opposite (i.e., disposed left and right) and disposed symmetrically. Each of the second guide groups 354 has a plurality of broken holes (three broken holes are schematically shown) 354a and a plurality of adjustment holes (two adjustment holes are schematically shown) 354b, wherein the plurality of broken holes 354a are located between two adjustment holes 354b. The bearings 356 may be located on the second guide groups 354 and fixed with a rotating shaft 3561. The rotating shaft 3561 may pass through the adjustment hole 354b, and depending on the position of the rotating shaft 3561 located in the adjustment hole 354b, the second guide groups 354 located at the left and right sides may form a guide group with adjustable spacing. In this way, the appropriate spacing between the bearings may be adjusted so that the object 10 transported by the conveying module 350 may be placed in a neutral position. Moreover, the broken holes 354a of the second guide groups 354 may absorb and/or buffer the force of impact between the object 10 and the bearings 356 when the object 10 enters and exits the inlet/outlet E, and may be used to reduce damage to the edge of the object 10. That is, when the broken holes 354a of the second guide group 354 are hit by the object 10, the broken holes 354a are compressed and absorb the impact force, thus having the effects of being compressible, shock-absorbing, and/or buffering. In an embodiment, the material of the second guide groups 354 may be, for example, deformable plastic, but the disclosure is not limited thereto. Moreover, the plurality of bearings 353 may be disposed on the first guide group 352 adjacent to the inlet/outlet E, and the plurality of bearings 353 may be arranged in an inclined manner, and the width of the bearings forming the opposite sides of the inlet/outlet E appears wider at the inlet/outlet E and is gradually reduced to the direction of the accommodation space S to form the function of forming progressive guidance to provide the function of smoothly guiding the object 10 into and out of the inlet/outlet E.

In addition, please refer to FIG. 1B and FIG. 3A at the same time. The partition 320 is located between the conveying module 350 and the lifting module 360. In an embodiment, the partition 320 may be fixed on the conveying module 350, so the space size of the first area S1 and the second area S2 of the accommodation space S is changed due to the lifting of the lifting module 360. The lifting of the lifting module 360 may assist in the input and output of the object 10 from the inlet/outlet E, and during the transfer process of the automated transport carrier 100, the center of mass position of the automated transport carrier 100 may be adjusted downward by lowering the height of the lifting module 360 to facilitate the movement of the automated transport carrier 100 to reduce the possibility of the automated transport carrier 100 tipping over.

Specifically, the lifting module 360 of the present embodiment includes a front scissor mechanism 362, a rear scissor mechanism 364, a front sliding wheel 366, a rear sliding wheel 368, a stretching rod 365, and a driving motor 367. Using a double scissor mechanism (i.e., the front scissor mechanism 362 and the rear scissor mechanism 364) with the driving motor 367 can, for example, achieve a lifting stroke of 95 mm. That is, the lifting range of the lifting module 360 of the present embodiment is, for example, between 0 mm and 95 mm, but the disclosure is not limited thereto. Since both the front and rear are equipped with a scissor mechanism, when the lifting reaches the highest point, there are still two contact points as support. The stretching rod 365 is used in the middle to enhance the rigidity of the front and rear structures to provide stable and/or reliable lifting stroke of the lifting module 360. Moreover, the bottom of the lifting module 360 of the present embodiment is also equipped with two sets of front sliding wheels 366 and rear sliding wheels 368 that may be made of low-dust-generating materials and may reduce particles generated by long-term operation wear. In addition, the accommodation device 300 of the present embodiment is also equipped with a barcode reader 370 to read the identification number of the object 10 located in the accommodation device 300.

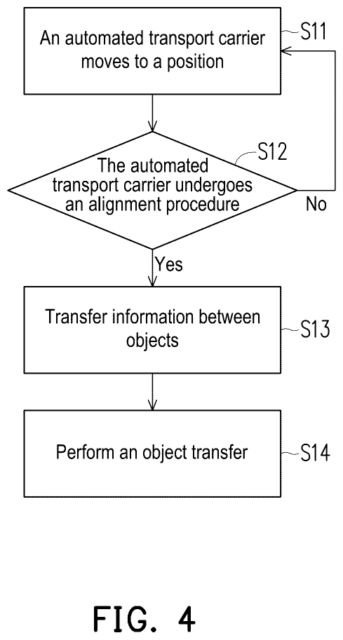

FIG. 4 is a schematic flowchart of an operation method of an automated transport carrier according to an embodiment of the disclosure. Please refer to FIG. 1A and FIG. 4 at the same time. The automated transport carrier is to receive an object on the machine. The steps thereof include: first, in step S11, the automated transport carrier 100 is moved to a position, such as at a vertical corner of the machine. Next, in step S12, the automated transport carrier 100 performs an alignment process, that is, the automated transport carrier 100 performs alignment via the lateral shift detection alignment sensor 400 and moves the automated transport carrier 100 to a position where the object 10 may be received correctly. Next, in step S13, the information of the transferred object is communicated, such as signal transmission confirmation via the programmed input/output communication module 500. Then, in step S14, the object is transferred, for example, the object is transferred from the machine to the accommodation space 300. In other words, the automated transport carrier 100 and the machine confirm each other before exchanging objects to prevent the object from being damaged due to the machine automatically transporting the object 10 before the automated transport carrier 100 is moved to the correct position to receive the object 10. In short, the automated transport carrier 100 of the present embodiment may be equipped with an intelligent positioning function. The alignment reference may be enhanced via the lateral shift detection alignment sensor 400 and the programmed input/output communication module 500 for secondary positioning, thereby improving the ability of precise positioning.

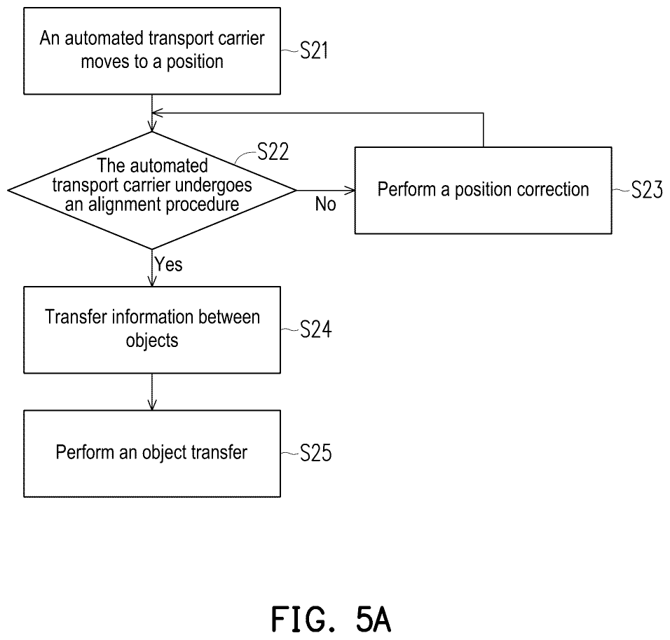

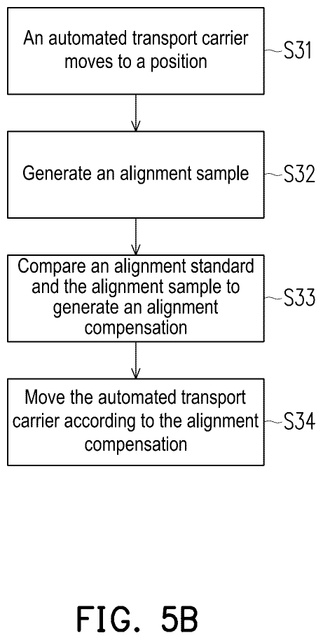

FIG. 5A is a schematic flowchart of an operation method of another automated transport carrier according to an embodiment of the disclosure. Please refer to FIG. 1A and FIG. 5A at the same time. The automated transport carrier 100 of the present embodiment may be equipped with an intelligent positioning function. Specifically, first, in step S21, the automated transport vehicle 100 is moved to positioning. Next, in step S22, the automated transport vehicle 100 performs an alignment process, such as generating an alignment sample by taking a photo, and comparing the alignment sample with a standard sample via software having an intelligent positioning function. If the spacing in space between the alignment sample and the standard sample is too large, that is, the alignment is outside the allowable range, the alignment process result is negative, and step S23 is performed to perform position correction. After the position correction is performed, step S22 is performed again to make the automated transport carrier 100 perform the alignment process. If the spacing in space between the alignment sample and the standard sample is within the allowable range, that is, the alignment falls within the allowable range, then the result of the alignment process is yes, then step S24 is performed to transfer information exchange of objects. Lastly, in step S25, the object is transferred. In the present embodiment, when it is found after the alignment process that there is an error and/or offset in the position of the automated transport carrier 100 (the alignment result is no), the automated transport carrier 100 may be returned to the starting point, moved to positioning, and then the alignment process is performed again until the alignment process result is yes.

FIG. 5B is a schematic flowchart of an operation method of another automated transport carrier according to an embodiment of the disclosure. Please refer to FIG. 1A and FIG. 5B at the same time. The automated transport carrier 100 of the present embodiment may be equipped with an intelligent positioning function. First, in step S31, the automated transport vehicle 100 is moved to positioning. Next, in step S32, an alignment sample is generated, for example, an alignment sample is generated by taking a photo. Next, in step S33, the alignment standard and the alignment sample are compared to generate a displacement compensation value. Next, in step S34, the automated transport carrier 100 is moved according to the displacement compensation value. That is, when it is found that there is an error and/or offset in the position of the automated transport carrier 100, position compensation may be performed. The difference from the embodiment of FIG. 5A is that the automated transport carrier 100 does not need to return to the starting point and then move again to perform the alignment process, thus shortening the time of the alignment process.

Based on the above, in the design of the accommodation device of the disclosure, the walls may define the accommodation space, and the partition may divide the accommodation space into the first area and the second area. The air blowing unit disposed in the first area may blow the air to the first area. Compared with the prior art of using personnel to transport the object, when the accommodation device of the automated transport carrier of the disclosure receives the object, in addition to replacing the existing manual transport, since the accommodation device includes the design of the walls, the object may be effectively protected to avoid the risk of damage to the object during transport. In addition, since the accommodation device of the disclosure includes the air blowing unit, the degree of contamination of the object by suspended particles may be effectively reduced.

Although the disclosure has been described with reference to the above embodiments, it will be apparent to one of the ordinary skill in the art that modifications and variations to the described embodiments may be made without departing from the spirit and scope of the disclosure. Accordingly, the scope of the disclosure will be defined by the attached claims not by the above detailed descriptions.

What is claimed is:

1. An accommodation device, comprising:
a plurality of walls defining an accommodation space;
a partition disposed in the accommodation space to divide the accommodation space into a first area and a second area; and
an air blowing unit disposed in the first area and blowing an air to the first area.

2. The accommodation device of claim 1, wherein the air blowing unit sucks in an external air and blows the air out to the first area.

3. The accommodation device of claim 2, wherein a cleanliness of the air is higher than a cleanliness of the external air.

4. The accommodation device of claim 1, wherein the air flows from the first area to the second area.

5. The accommodation device of claim 1, wherein the partition is separated from at least one of the walls.

6. The accommodation device of claim 1, wherein the first area is used to accommodate an object.

7. The accommodation device of claim 6, wherein the object comprises a carrier board and at least one electronic element disposed on the carrier board.

8. An automated transport carrier, comprising:
a mobile base; and
an accommodation device disposed on the mobile base, the accommodation device comprising:
a plurality of walls defining an accommodation space;
a partition disposed in the accommodation space to divide the accommodation space into a first area and a second area; and
an air blowing unit disposed in the first area and blowing an air to the first area.

9. The automated transport carrier of claim 8, wherein the air blowing unit sucks in an external air and blows the air out to the first area.

10. The automated transport carrier of claim 9, wherein a cleanliness of the air is higher than a cleanliness of the external air.

11. The automated transport carrier of claim 8, wherein the air flows from the first area to the second area.

12. The automated transport carrier of claim 8, wherein the partition is separated from at least one of the walls.

13. The automated transport carrier of claim 8, wherein the first area is used to accommodate an object.

14. The automated transport carrier of claim 13, wherein the object comprises a carrier board and at least one electronic element disposed on the carrier board.

15. An operation method of an automated transport carrier, comprising:
providing an automated transport carrier, wherein the automated transport carrier comprises an accommodation device, and the accommodation device comprises an air blowing unit;
making the accommodation device receive an object; and
making the air blowing unit blow an air to an inside of the accommodation device.

16. The operation method of the automated transport carrier of claim 15, wherein the accommodation device comprises a plurality of walls to define an accommodation space to accommodate the object.

17. The operation method of the automated transport carrier of claim 16, wherein the accommodation device further comprises a partition disposed in the accommodation space to divide the accommodation space into a first area and a second area, and the first area is adjacent to the air blowing unit and used to accommodate the object.

18. The operation method of the automated transport carrier of claim 17, wherein the partition is separated from at least one of the walls.

19. The operation method of the automated transport carrier of claim 17, wherein the air flows from the first area to the second area.

20. The operation method of the automated transport carrier of claim 15, wherein the air blowing unit sucks in an external air and blows the air to the inside of the accommodation device.
